(19) United States
(12) Patent Application Publication
(10) Pub. No.: US 2011/0017258 A1
(43) Pub. Date: Jan. 27, 2011

(54) SOLAR CELL AND FABRICATION METHOD THEREOF

(75) Inventors: Il-Hyoung Jung, Seoul (KR); Ju-Hwan Yun, Seoul (KR); Jong-Hwan Kim, Seoul (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 12/740,327

(22) PCT Filed: Jul. 11, 2008
(86) PCT No.: PCT/KR08/04116

§ 371 Date: Sep. 20, 2010

(30) Foreign Application Priority Data
Jan. 7, 2008 (KR) 10-2008-0001764

(51) Int. Cl. H01L 31/042; H01L 21/00

(52) U.S. Cl. 136/244; 438/57; 257/E21.001

(57) ABSTRACT

A back contact solar cell comprises a first dopant diffusion part and a second dopant diffusion part formed on a rear surface of an n-type semiconductor wafer with a predetermined distance formed therebetween by a diffusion prevention part for ensuring no contact with each other and suppressing the diffusion of dopant; and an electrode configured of an anode and a cathode each connected to the first dopant diffusion part and the second dopant diffusion part. According to the present invention, the back contact solar cell is capable of preventing light loss and improving its efficiency by forming an electrode to be positioned on a rear surface of a semiconductor wafer through a simple process and by simultaneously implementing an anode electrode and a cathode electrode on the semiconductor wafer without having a grid electrode restricting incidence of sunlight.

### TECHNICAL FIELD

The present invention relates to a back contact solar cell and a fabrication method thereof, and more specifically to a back contact solar cell and a fabrication method thereof capable of preventing light loss and improving its efficiency by forming an electrode to be positioned on a rear surface of a semiconductor wafer through a simple process and by simultaneously implementing an anode electrode and a cathode electrode on the semiconductor wafer without having a grid electrode restricting incidence of sunlight.

### BACKGROUND ART

Interest in new renewable energy is increasing due to the recent swift rise of oil prices, earth's environmental problems, fossil fuel depletion, nuclear waste disposal problems from nuclear power generation, and position selection problems according to construction of new power plants, or the like. Among others, research and development on a solar cell being a pollution-free energy source has actively been progressed.

A solar cell, which is an apparatus converting light energy into electric energy using a photovoltaic effect, is sorted into a silicon solar cell, a thin film solar cell, a dye sensitized solar cell, and an organic polymer solar cell, etc. according to its components. The solar cell is independently used as a main power supply for an electronic watch, a radio, a manless lighthouse, a satellite, a rocket, etc. and is also used as an auxiliary power supply in connection with a system of a commercial AC power supply. Interest in solar cells is increasing with the increase of need for alternative energy.

The solar cell is being developed and commercialized in various types. Among others, a back contact solar cell has several advantages, compared with a conventional silicon solar cell having contacts on a front surface and a rear surface thereof. One of the advantages is higher conversion efficiency due to reduction or removal of contact obscuration losses. Also, since the contacts having two polarities are positioned on the same surface, the back contact solar cell can easily be installed in an inside of a predetermined circuit and thus, the installation cost thereof can be reduced.

A general back contact solar cell having these advantages may include an n-type substrate or a p-type substrate and a high-density doped emitter (n++ and p++) and may include front and rear passivation layers for increasing light conversion efficiency.

As a fabrication method of the back contact silicon solar cell, there are a metallization wrap around (MWA) method, a metallization wrap through (MWT) method, an emitter wrap through (EWT) method, and a method using a back-junction structure, etc.

However, these methods need a complicated etching process upon forming an electrode including an anode part and a cathode part. Also, a grid electrode should be formed on the front surface of the solar cell to form the electrode. This leads to a problem of a restriction of the incidence of sunlight by a formation area of the grid electrode and a deterioration of the efficiency of the solar cell accordingly.

Accordingly, a fabrication method of the back contact solar cell capable of forming the electrode and improving the efficiency of the solar cell through a simple process is needed.

### DISCLOSURE OF INVENTION

### Technical Problem

The present invention proposes to solve the foregoing problems. It is an object of the present invention to provide a fabrication method of a back contact solar cell and a back contact solar cell fabricated using the same capable of facilitating a modulation process and reducing its production costs by forming an electrode for the back contact solar cell through a simple process.

It is another object of the present invention to provide a fabrication method of a back contact solar cell and a back contact solar cell fabricated using the same capable of improving its efficiency by maximizing an incidence amount of sunlight without having a grid electrode, etc. upon forming an electrode for the back contact solar cell.

It is yet another object of the present invention to provide a fabrication method of a back contact solar cell and a back contact solar cell fabricated using the same capable of excluding film damage of a passivation layer due to a high temperature process by a final process of forming a front passivation layer made of silicon nitride, etc. in the back contact solar cell.

### Technical Solution

To achieve the aforementioned objects, there is provided a back contact solar cell according to one embodiment of the present invention comprising: a first dopant diffusion part and a second dopant diffusion part formed on a rear surface of an n-type semiconductor wafer with a predetermined distance formed therebetween by a diffusion prevention part for ensuring no contact with each other and suppressing the diffusion of dopant; and an electrode configured of an anode and a cathode each connected to the first dopant diffusion part and the second dopant diffusion part.

In the present invention, the first dopant may be any one p-type dopant selected from materials consisting of Group III elements and the second dopant may be any one n-type dopant selected from materials consisting of Group V elements. The first dopant and the second dopant are different types from each other and may be selected from other Group elements.

In the present invention, the back contact solar cell may further comprise a passivation layer on the front and/or the rear surface of the semiconductor wafer.

In the present invention, the form of the first dopant diffusion part and the second dopant diffusion part is not limited, but the first dopant diffusion part and the second dopant diffusion part may take a form to be inserted in shift in mutual areas without contacting each other. Preferably, they may take a herringbone form or a comb-shaped form so as to be crossly formed in mutual areas without contacting each other.

To achieve the aforementioned objects, a fabrication method of a back contact solar cell according to one embodiment of the present invention comprises the steps of: forming a first dopant diffusion part on a rear surface of an n-type semiconductor wafer; forming a diffusion prevention part for suppressing the diffusion of dopant around the first dopant diffusion part; forming a second dopant diffusion part on a rear surface of an n-type semiconductor wafer on which the first dopant diffusion part and the diffusion prevention part are not formed; and forming an electrode configured of an anode and a cathode each connected to the first dopant diffusion part and the second dopant diffusion part.

The first dopant diffusion part may be formed by applying first dopant paste on a predetermined place of the rear surface of the n-type semiconductor wafer and then performing heat treatment thereon.

The first dopant paste may be a dopant solution including any one p-type dopant selected from materials consisting of Group III elements. The first dopant paste is particularly not limited, but the form of dopant solution is preferably dopant paste having appropriate viscosity.

Preferably, as the p-type semiconductor dopant, there are boron (B), aluminum (Al), gallium (Ga), indium (In), etc.

In the present invention, the second dopant diffusion part may be formed by applying second dopant paste on the rear surface of the n-type semiconductor wafer on which the first dopant diffusion part and the diffusion prevention part are not formed and then performing heat treatment thereon.

The second dopant paste may be a dopant solution including any one n-type dopant selected from materials consisting of Group V elements. The second dopant paste is not limited, but the form of dopant solution is preferably dopant paste having high viscosity. Preferably, as the n-type semiconductor dopant, there are phosphorous (P), arsenic (As), etc.

The viscosity of the dopant paste is not limited, but it preferably has enough viscosity allowing the dopant solution not to run when it is applied on the surface of the wafer.

In the present invention, the heat treatment temperature performed after applying the first dopant paste or the second dopant paste is not limited, but it may preferably be 500° C. to 1000° C.

In the present invention, the method may further comprise the step of forming a rear passivation layer on the rear surface of the semiconductor wafer, before the step of forming the electrode.

The rear passivation layer may be formed of a rapid thermal oxide (RTO) layer or an amorphous silicon layer and is not limited thereto. The component of the rear passivation layer may be formed by the rapid thermal process (RTO) method or the sputtering method, but it is not necessarily limited thereto. Accordingly, any methods of forming the passivation layer according to technology known to those skilled in the art can be used.

The temperature for performing the rapid thermal process method may be 700° C. to 1100° C.

In the present invention, the method may further comprise the step of forming a front passivation layer on the front surface of the semiconductor wafer, after the step of forming the electrode.

The front passivation layer may be a silicon nitride layer, but it is not limited thereto. Accordingly, any methods of forming the passivation layer according to technology known to those skilled in the art can be permitted. The back contact solar cell has an effect of excluding the film damage of the passivation layer due to the high temperature process by a final process of forming the front passivation layer made of silicon nitride, etc.

In the present invention, the terms, the front and the rear are based on the incidence light of the solar cell and one ‘surface’ on which incident light is incident is referred to the ‘front surface’ and the other surface opposite to the front surface is referred to as the ‘rear surface’.

In the present invention, the formation of the first dopant diffusion part, the diffusion prevention part, and the second dopant diffusion part may be performed by a screen printing method or a printing method, but it is not limited thereto. Accordingly, any technologies known to those skilled in the art can be used.

In the fabrication method of the solar cell of the present invention, after forming the first dopant diffusion part as diffusion paste by the screen printing method and forming the diffusion prevention part around the first dopant diffusion part, the first dopant diffusion part is subjected to a drying and heat treatment process at high temperature, making it possible to prevent the continuous diffusion of the first dopant part. The diffusion prevention part is formed to form the diffusion barrier and the second dopant diffusion part being the semiconductor dopant which is a different type from the first dopant may be formed as diffusion paste by the screen printing method.

According to one aspect of the present invention, the step of forming the first dopant diffusion part, the diffusion prevention part, and the second dopant diffusion part may comprise the steps of: forming a first dopant, a diffusion prevention material, and a second dopant, respectively, in a predetermined region by printing them; after forming the respective materials, performing a drying and a firing, respectively, and cleaning them with materials, such as hydrogen fluoride (HF), etc.

In particular, the firing process in each step may be performed at a high temperature of 500° C. to 1000° C.

In the present invention, the electrode connected to the first dopant diffusion part and the second dopant diffusion part may be formed by overlapping and printing materials, such as silver (Ag), aluminum (Al), zinc oxide/silver (ZnO/Ag), zinc oxide/aluminum (ZnO/Al), etc. on the dopant diffusion part. Therefore, the present invention forms the electrode terminals of the anode and the cathode on the same surface on the rear of the semiconductor wafer, making it possible to simplify the process and to maximize the efficiency.

A fabrication method of a back contact solar cell according to another aspect of the present invention comprises the steps of: forming a p-type semiconductor region by forming a rear contact layer including any one p-type dopant selected from materials consisting of Group III elements on a predetermined place of a rear of an n-type semiconductor wafer, and heat-treating the rear contact layer; forming a diffusion prevention part for suppressing the diffusion of p-type dopant around the p-type semiconductor region; forming an n-type semiconductor region on a rear surface of an n-type semiconductor wafer on which the p-type semiconductor region and the diffusion prevention part are not formed; and forming an electrode including an anode and a cathode connected to the p-type semiconductor region and the n-type semiconductor region respectively. That is, the said electrodes can include an anode connected to the p-type semiconductor region and a cathode connected to the n-type semiconductor region.

At this time, the rear contact layer may be made of aluminum (Al) or boron (B). In the rear contact layer, the aluminum or boron being the materials of the rear contact layer acts as the p-type dopant by heat treatment to convert the predetermined region on the rear surface of the n-type semiconductor wafer into the P+ semiconductor region. At this time, the heat treatment temperature is not limited, but it may be 500° C. to 1000° C.

An interface of the rear surface of the n-type semiconductor wafer and the rear contact layer forms a p-n junction through the heat treatment process. In particular, when the material of the rear contact layer is aluminum, it is doped at low concentration so that the diffusion thereof into silicon, being a material of the n+ semiconductor wafer, is restricted upon performing the heat treatment, thereby forming a relatively thin p-n junction. Also, the formed p+ semiconductor region reduces the rear recombination of electrons generated by light to perform a function of improving the efficiency of the solar cell. Thereby, a phosphorous oxychloride (POCl₃) diffusion process required for the conventional p-n junction can be omitted, making it possible to simplify the process and to reduce the costs.

In the present invention, when the material of the rear contact layer is boron, it is doped at high concentration in the later heat treatment process, making it possible to form a thick p-n junction.

In accordance with one embodiment of the present invention, the n-type semiconductor wafer substrate may be a silicon wafer formed by a structured Czochralski (Cz) silicon single crystal growth method to minimize the recombination of carriers generated by light during the operation of the solar cell. Also, the n-type semiconductor wafer substrate may have a prominence and depression structure to improve the efficiency of the solar cell.

### ADVANTAGEOUS EFFECTS

According to the present invention, in fabricating the back contact solar cell, the electrode can be formed through the simple process without using the etching process, making it possible to facilitate the modulation process and to reduce the production costs.

Also, the solar cell of the present invention forms the electrode in the back contact way so as to remove an area restricting the incidence of sunlight due to the grid electrode, etc., making it possible to improve the efficiency of light.

### BRIEF DESCRIPTION OF THE DRAWINGS

These and other objects, features, aspects, and advantages of the present invention will be more fully described in the following detailed description of preferred embodiments and examples, taken in conjunction with the accompanying drawings. In the drawings:

FIGS. 1 and 2 are perspective views showing a configuration of a back contact solar cell according to one embodiment of the present invention.

FIG. 3 is a flow chart showing a fabrication process of a back contact solar cell according to one embodiment of the present invention.

### BEST MODE FOR CARRYING OUT THE INVENTION

Hereinafter, the embodiments of the present invention will be described with reference to the accompanying drawings.

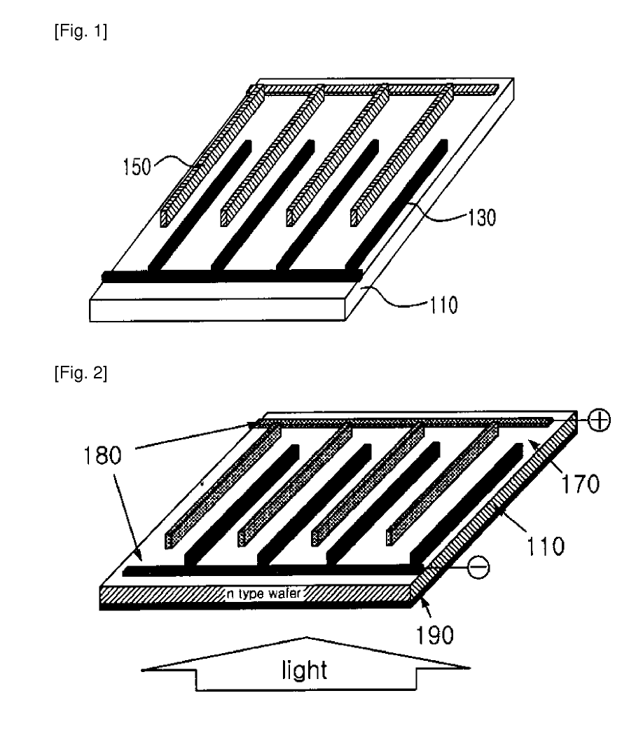

FIG. 1 is a perspective view showing a configuration of a back contact solar cell according to one embodiment of the present invention. First, FIG. 1 shows a shape that an n-type dopant diffusion part and a p-type dopant diffusion part are formed during a fabrication process of a solar cell and FIG. 2 shows a shape of the solar cell after all the processes are completed.

As shown in FIG. 2, the back contact solar cell of the present invention includes a semiconductor wafer 110 and an electrode 180 formed on a rear surface of the wafer.

In the conventional solar cell, a grid electrode should be disposed on an incidence surface of sunlight to form an electrode such that the incidence of sunlight is restricted by the occupied area of the grid electrode, thereby reducing the efficiency of the solar cell. However, the solar cell of the present invention forms the electrode 180 in a back contact way to remove an area restricting the incidence of sunlight, thereby significantly improving the efficiency of the solar cell.

Also, the electrode 180 is formed by a known printing method without using an etching process, making it possible to fabricate the solar cell at low cost.

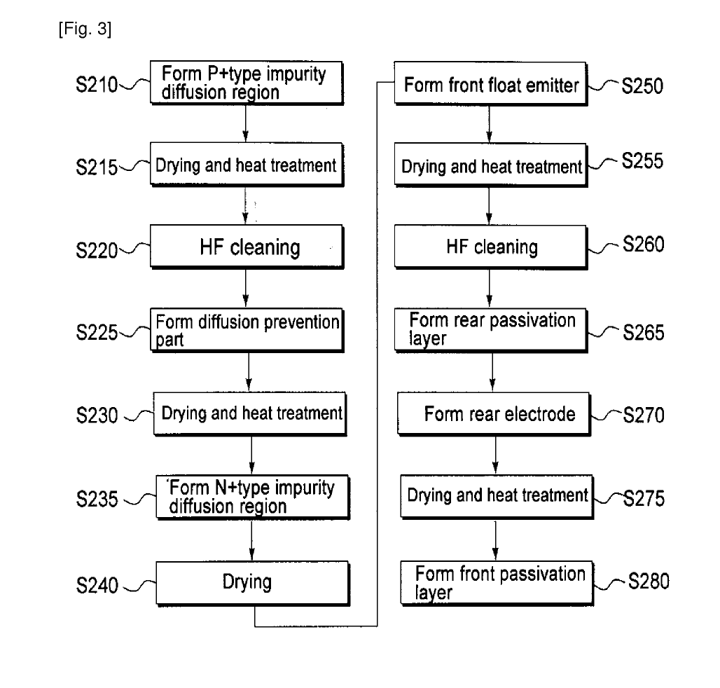

FIG. 3 is a flow chart showing a fabrication process of a back contact solar cell according to one embodiment of the present invention. Hereinafter, the fabrication process of the back contact solar cell will be described with reference to FIGS. 1 to 3.

As shown in FIG. 3, first, a p-type dopant is applied (S210) on a rear surface of a semiconductor wafer 110 to form a p-type dopant diffusion part 130. A drying and a heat treatment processes are performed (S215) after an application of the p-type dopant. The p-type dopant may be applied to form the p-type dopant diffusion part 130 in a plurality of line shapes apart from each other. Thus, the p-type dopant diffusion part 130 is disposed to be spaced apart from other regions thereof by a predetermined distance. The p-type dopant material may generally be formed in a herringbone form.

The p-type dopant may be a material consisting of Group III elements. One example of the materials may include boron (B). Meanwhile, the application may be performed by a known printing method, etc. and the drying may be performed by a rapid thermal process (RTP). The RTP may be performed inside a furnace at about 100° C. to 300° C. The p-type dopant is applied on the wafer substrate by the drying and the heat treatment to result in solid-phase diffusion into the wafer substrate, thereby forming the p-type dopant diffusion part 130.

Next, a cleaning process is performed (S220) to remove unnecessary oxide, etc. using materials, such as hydrogen fluoride (HF), or the like, and material paste for diffusion prevention is applied to form a diffusion prevention part (S225).

Generally, if the p-type dopant diffusion part 130 is formed on the semiconductor wafer substrate 110, the p-type dopant is diffused into the substrate 110 by the solid phase diffusion to form a predetermined region. Also, an n-type dopant diffusion part 150 formed later diffuses an n-type dopant into the substrate 110 by the solid phase diffusion to form an n-type dopant diffusion region.

However, in such a diffusion process, the solid phase diffusion as well as gas phase diffusion into the semiconductor wafer 110 occur together. In other words, the diffusion by the respective types of dopant diffusion parts can be caused toward the air in all directions by gas phase diffusion, not only toward the semiconductor wafer 110.

Thereby, in the diffusion by the n-type dopant diffusion part 150, the diffusion to the previously formed p-type diffusion part can also be caused at the same time.

Therefore, in order to prevent this phenomenon, the diffusion prevention part as a diffusion barrier to the n-type dopant diffusion part 150 to be formed later is formed around the region in which the p-type dopant diffusion part 130 is formed.

The form of the diffusion prevention part is not limited to a specific form and width, but it can be formed around the place applied with the p-type dopant diffusion part 130 to form the interface with the n-type dopant diffusion part 150 to be applied later. Also, the diffusion prevention part may be made of materials, such as TiO₂, but it is not limited thereto.

Meanwhile, the application of the diffusion prevention part can be formed by a known screen printing method or printing method.

After the paste of the diffusion prevention part is applied, the drying and the heat treatment are performed (S230), thereby making it possible to form the diffusion barrier layer on the substrate 110. The heat treatment can be performed at about 500° C. to 1000° C.

Next, the n-type dopant paste is applied (S235) on a region opposite to the region applied with the p-type dopant paste by interposing the region where the paste for the diffusion prevention part is applied. Since the paste of the diffusion prevention part forms the interface of the p-type dopant diffusion part 130 and the n-type dopant diffusion part 150, the p-type dopant diffusion part 130 and the n-type dopant diffusion part 150 may be each formed in a herringbone form or a comb-shaped form engaged with each other.

The n-type dopant diffusion part 150 may be made of materials consisting of Group V elements, wherein one example of the materials includes phosphorous (P).

After the drying process is performed (S240), the n-type dopant diffusion region is formed by the diffusion of the n-type dopant diffusion part 150 and then a front float emitter is formed (S250).

Herein, the method of forming the p-type dopant diffusion part 130 by applying the p-type dopant, forming the diffusion prevention part by applying the paste for diffusion prevention, and then forming the n-type dopant diffusion part 150 by the n-type dopant is described as an example, but the solar cell may be fabricated in the order of forming the n-type dopant diffusion part 150, applying and forming the diffusion prevention part and then forming the p-type dopant diffusion part 130.

Next, the drying and the heat treatment processes are performed (S255) and the unnecessary oxide, etc. produced during the diffusion of fluoride is removed (S260) by cleaning with the hydrogen fluoride (HF),

Thereafter, a rear passivation layer 170 is formed (S265) on the semiconductor wafer 110 on which the n-type dopant diffusion part 150 and the p-type dopant diffusion part 130 are formed. The rear passivation layer 170 may be heat oxide formed by a rapid thermal oxidation (RTO) method performed in the inside of a furnace for the RTO. The internal temperature of the furnace may be about 700° C. to 1000° C. Also, the rear passivation layer 170 may be formed by the sputtering method using silicon oxide (SiO₂) as a target material. The formation thickness of the rear passivation layer 170 may be several nm to several hundreds of nm, preferably about 20 nm to 50 nm. The rear passivation layer 170 as one embodiment of the present invention may be formed of a metal rapid thermal oxide layer or an amorphous silicon layer formed by the rapid thermal process (RTP) method or a sputtering method.

After forming the rear passivation layer 170, the electrode 180 is formed (S270) on the rear surface of the semiconductor wafer 110 of the solar cell. The rear electrode 180 may be formed along the region in which the n-type dopant diffusion part 150 and the p-type dopant diffusion part 130 are formed, wherein each of the electrodes formed along the n-type dopant diffusion part 150 and the p-type dopant diffusion part 130 functions as an anode part and an cathode part. The electrode 180 may be made of conductive materials, such as silver (Ag), aluminum (Al), etc. A deposition method, a screen printing method, or a printing method, all of which are known, may be used as a formation method.

After printing the rear electrode 180, the drying and the heat treatment processes are performed (S275) to cure the electrode 180.

Thereafter, the front passivation layer 190 is finally formed (S280) on the front surface of the semiconductor wafer 110, so that the fabrication of the solar cell is completed. The front passivation layer 190 may be made of materials such as silicon nitride SiNₓ, etc. and may be formed using a known coating method, etc.

The semiconductor wafer used in one embodiment of the present invention may be a variety of known wafer substrates and therefore, is not limited. However, it may preferably be an n-type silicon semiconductor wafer.

The present invention process does not use an etching process for forming the electrode, making it possible to simplify the process and facilitate the modulation process. Thereby, the production costs can be reduced.

Also, a conventional solar cell should have the grid electrode on the incidence surface of sunlight to form the electrode such that the light incidence is restricted by the occupied area of the grid electrode, thereby degrading the efficiency of the solar cell, while the present invention forms the electrode by the back contact way so as to remove the area restricting the incidence of sunlight, making it possible to significantly improve the efficiency of the solar cell.

Also, the formation process of the front passivation layer made of silicon nitride, etc. is finally performed, making it possible to exclude the film damage of the passivation layer due to the high temperature process.

According to the present invention, in fabricating the back contact solar cell, the electrode can be formed through the simple process without using the etching process, making it possible to facilitate the modulation process and to reduce the production costs.

Also, the solar cell of the present invention forms the electrode in the back contact way so as to remove an area restricting the incidence of sunlight due to the grid electrode, etc., making it possible to improve the efficiency of light.

Although preferred embodiments of the present invention have been shown and described, it would be appreciated by those skilled in the art that changes and modifications might be made in these embodiments without departing from the principles and spirit of the invention, the scope of which is defined in the claims and their equivalents. Also, the materials of each component described in the specification can easily be selected and substituted from various materials known to those skilled in the art. Also, those skilled in the art can omit a part of the components described herein without degrading the performance or can add components to improve the performance. Also, those skilled in the art can change a sequence of the process steps described herein according to the process environment or the process apparatus. Therefore, the scope of the present invention must be defined by the claims and their equivalents rather than the foregoing embodiments.

### INDUSTRIAL APPLICABILITY

According to the present invention, in fabricating the back contact solar cell, the electrode can be formed through the simple process without using the etching process, making it possible to facilitate the modulation process and to reduce the production costs.

Also, the solar cell of the present invention forms the electrode in the back contact way so as to remove an area restricting the incidence of sunlight due to the grid electrode, etc., making it possible to improve the efficiency of light.

1. A solar cell comprising:
a first dopant diffusion part and a second dopant diffusion part formed on a rear surface of an n-type semiconductor wafer with a predetermined distance formed therebetween by a diffusion prevention part for ensuring no contact with each other and suppressing the diffusion of dopant; and
an electrode configured of an anode and a cathode each connected to the first dopant diffusion part and the second dopant diffusion part.

2. The solar cell according to claim 1, wherein the first dopant is any one p-type dopant selected from materials consisting of Group III elements and the second dopant is any one n-type dopant selected from materials consisting of Group V elements.

3. The solar cell according to claim 1, further comprising a passivation layer on the front and/or the rear surface of the semiconductor wafer.

4. The solar cell according to claim 1, wherein the first dopant diffusion part and the second dopant diffusion part take a form to be inserted in shift in mutual areas without contacting each other.

5. The solar cell according to claim 1, wherein the first dopant diffusion part and the second dopant diffusion part have an opposite comb-shaped form or an opposite herringbone form, respectively.

6. A fabrication method of a solar cell comprising the steps of: forming a first dopant diffusion part on a rear surface of an n-type semiconductor wafer;
forming a diffusion prevention part for suppressing the diffusion of dopant around the first dopant diffusion part;
forming a second dopant diffusion part on the rear surface of the n-type semiconductor wafer on which the first dopant diffusion part and the diffusion prevention part are not formed; and
forming an electrode configured of an anode and a cathode each connected to the first dopant diffusion part and the second dopant diffusion part.

7. The fabrication method according to claim 6, wherein the first dopant diffusion part is formed by applying first dopant paste on a predetermined place of the rear surface of the n-type semiconductor wafer and then performing heat treatment thereon.

8. The fabrication method according to claim 7, wherein the first dopant paste is dopant paste including any one p-type dopant selected from materials consisting of Group III elements.

9. The fabrication method according to claim 6, wherein the second dopant diffusion part is formed by applying second dopant paste on the rear surface of the n-type semiconductor wafer on which the first dopant diffusion part and the diffusion prevention part are not formed and then performing heat treatment thereon.

10. The fabrication method according to claim 9, wherein the second dopant paste is dopant paste including any one n-type dopant selected from materials consisting of Group V elements.

11. The fabrication method according to claim 7, wherein the heat treatment temperature is 500° C. to 1000° C.

12. The fabrication method according to claim 6, further comprising the step of forming a rear passivation layer on the rear surface of the semiconductor wafer, before the step of forming the electrode.

13. The fabrication method according to claim 12, wherein the rear passivation layer is a rapid thermal oxide (RTO) layer or an amorphous silicon layer.

14. The fabrication method according to claim 12, wherein the rear passivation layer is formed by a rapid thermal process (RTO) method or a sputtering method.

15. The fabrication method according to claim 14, wherein the temperature for performing the rapid thermal process method is 700° C. to 1100° C.

16. The fabrication method according to claim 6, further comprising the step of forming a front passivation layer on the front surface of the semiconductor wafer, after the step of forming the electrode.

17. The fabrication method according to claim 16, wherein the front passivation layer is a silicon nitride layer.

18. The fabrication method according to claim 6, wherein the first dopant diffusion part, the diffusion prevention part, and the second dopant diffusion part are formed by a screen printing method or a printing method.

19. A fabrication method of a solar cell comprising the steps of: forming a p-type semiconductor region by forming a rear contact layer including any one p-type dopant selected from materials consisting of Group III elements on a predetermined place of a rear of an n-type semiconductor wafer, and heat-treating the rear contact layer;
forming a diffusion prevention part for suppressing the diffusion of p-type dopant around the p-type semiconductor region;
forming an n-type semiconductor region on a rear surface of an n-type semiconductor wafer on which the p-type semiconductor region and the diffusion prevention part are not formed; and
forming an electrode configured of an anode and a cathode connected to the p-type semiconductor region and the n-type semiconductor region respectively.

20. The fabrication method according to claim 19, wherein the rear contact layer is made of aluminum (Al) or boron (B).
